(19) United States
(12) Patent Application Publication
(10) Pub. No.: US 2018/0034007 A1
(43) Pub. Date: Feb. 1, 2018

(54) Electrode Structure and Organic Light Emitting Unit and Manufacturing Method Thereof

(71) Applicant: BOE Technology Group Co., Ltd., Beijing (CN)

(72) Inventors: Xiaolong He, Beijing (CN); Shi Shu, Beijing (CN); Wei Xu, Beijing (CN); Zhanfeng Cao, Beijing (CN); Qi Yao, Beijing (CN)

(73) Assignee: BOE Technology Group Co., Ltd., Beijing (CN)

(21) Appl. No.: 15/126,839

(22) PCT Filed: Dec. 17, 2015
(86) PCT No.: PCT/CN2015/097728

§ 371 Date: Sep. 16, 2016

(30) Foreign Application Priority Data
Aug. 3, 2015 (CN) 201510482988.4

(51) Int. Cl. H01L 51/56; H01L 51/52

(52) U.S. Cl. CPC H01L 51/56; H01L 51/5209; H01L 51/5225

(57) ABSTRACT

An electrode structure and an organic light emitting unit and the manufacturing method thereof are disclosed. The electrode structure includes: a substrate; a plurality of strip-like partitions disposed on the substrate; and an electrode covering a surface of the substrate. The electrode includes a first portion located on a surface of each of the strip-like partitions and a second portion located between two adjacent strip-like partitions, each of the strip-like partitions includes an upper layer and a lower layer which are stacked with each other, the upper layer and the lower layer are made of different materials; a bottom surface of the upper layer completely covers a top surface of the lower layer, and a width of the bottom surface of the upper layer is larger than a width of the top surface of the lower layer in a plane perpendicular to an extending direction of the strip-like partitions.

### TECHNICAL FIELD

The present disclosure relates to an electrode structure, an organic light emitting unit and a manufacturing method of the organic light emitting unit.

### BACKGROUND

Due to the advantages such as high contrast, wide color gamut, low power consumption, thin thickness and light weight, organic light emitting display devices have drawn wide attentions and are widely applied in the fields such as high-end mobile phone and television.

A method for manufacturing a passive matrix organic light emitting device utilizes cathode separation pillars to pattern the cathode, for example, firstly forming cathode separation pillars on a substrate, then evaporating a metal for cathode to form strip electrodes between the separation pillars. However, a technique for preparing the cathode separation pillars employs an ultraviolet exposing process, which suffers from a high difficulty and is not easy to be controlled, and the material of the cathode separation pillars is a kind of modified negative photoresist, which has relatively high costs.

### SUMMARY

A first aspect of the present disclosure provides an electrode structure, comprising: a substrate; a plurality of strip-like partitions disposed on the substrate; and an electrode covering a surface of the substrate, the electrode comprises a first portion located on a surface of each of the strip-like partitions and a second portion located between two adjacent strip-like partitions. Each of the strip-like partitions comprises an upper layer and a lower layer which are stacked with each other, the upper layer and the lower layer are made of different materials; a bottom surface of the upper layer completely covers a top surface of the lower layer, and a width of the bottom surface of the upper layer is larger than that of the top surface of the lower layer in a plane perpendicular to an extending direction of the strip-like partitions.

A second aspect of the present disclosure provides an organic light emitting unit, comprising: a base substrate; a first electrode disposed on the base substrate; a plurality of strip-like partitions disposed on the first electrode; an organic light emitting layer disposed between two adjacent strip-like partitions; and a second electrode covering a surface of the base substrate, the second electrode comprises a first portion located on a surface of each of the strip-like partitions and a second portion located on a surface of the organic light emitting layer. Each of the strip-like partitions comprises a first material layer located at an lower layer and a second material layer located at an upper layer, the first material layer and the second material layer are made of different materials; a bottom surface of the upper layer completely covers a top surface of the lower layer, and a width of a bottom surface of the upper layer is larger than that of a top surface of the lower layer in a plane perpendicular to an extending direction of the strip-like partitions.

A third aspect of the present disclosure provides a manufacturing method of an organic light emitting unit, comprising: forming a first electrode on a base substrate; forming a first material layer on the first electrode; forming a second material layer on the first material layer and the patterning the second material layer to obtain a plurality of first strip-like members; etching the first material layer by way of the plurality of first strip-like members as a mask to obtain a plurality of second strip-like members, in this way, each of the first strip-like members and each of the second strip-like members which are stacked with each other constitute a strip-like partition; forming an organic light emitting layer among the plurality of strip-like partitions; and forming a second electrode on a surface of the substrate, the second electrode comprises a first portion located on a surface of each of the strip-like partitions and a second portion located on a surface of the organic light emitting layer; the first material layer and the second material layer are made of different materials; a width of a bottom surface of the second material layer is larger than that of a top surface of the first material layer, and the bottom surface of the second material layer completely covers the top surface of the first material layer.

### BRIEF DESCRIPTION OF THE DRAWINGS

In order to clearly illustrate the technical solutions of the embodiments of the present disclosure, the drawings of the embodiments will be briefly described in the following; it is obvious that the described drawings are only related to some embodiments of the disclosure and thus are not limitative of the present disclosure.

FIG. 1 schematically illustrates a plan view of an electrode structure according to an embodiment of the present disclosure;

FIG. 2 is a sectional view along line I-I in FIG. 1;

FIG. 3a schematically illustrates a plan view of an organic light emitting unit according to an embodiment of the present disclosure;

FIG. 3b is a sectional view along line II-II in FIG. 3a;

FIG. 4 is a flow diagram of a manufacturing method of an organic light emitting unit according to an embodiment of the present disclosure;

FIG. 5a schematically illustrates a plan view of a substrate of an organic light emitting unit according to an embodiment of the present disclosure;

FIG. 5b is a sectional view along line II-II in FIG. 5a;

FIG. 6a schematically illustrates a plan view of a substrate of an organic light emitting unit according to an embodiment of the present disclosure;

FIG. 6b is a sectional view along line II-II in FIG. 6a;

FIG. 7a schematically illustrates a plan view of a substrate of an organic light emitting unit according to an embodiment of the present disclosure;

FIG. 7b is a sectional view along line II-II in FIG. 7a;

FIG. 8 schematically illustrates a sectional view of a substrate of an organic light emitting unit according to an embodiment of the present disclosure;

FIG. 9 schematically illustrates a sectional view of a substrate of an organic light emitting unit according to an embodiment of the present disclosure;

FIG. 10 schematically illustrates a sectional view of a substrate of an organic light emitting unit according to an embodiment of the present disclosure;

FIG. 11a schematically illustrates a plan view of a substrate of an organic light emitting unit according to an embodiment of the present disclosure;

FIG. 11b is a sectional view along line II-II in FIG. 11a;

FIG. 12 is a scanning electron microscope image of a substrate according to an embodiment of the present disclosure;

FIG. 13 schematically illustrates a sectional view of a substrate of an organic light emitting unit according to another embodiment of the present disclosure;

FIG. 14 schematically illustrates a sectional view of a substrate of an organic light emitting unit according to another embodiment of the present disclosure; and

FIG. 15 schematically illustrates a sectional view of a substrate of an organic light emitting unit according to another embodiment of the present disclosure.

### DETAILED DESCRIPTION

In order to make objects, technical solutions and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

Unless otherwise defined, the technical terminology or scientific terminology used herein should have the same meaning as commonly understood by one of ordinary skill in the art to which this disclosure belongs. Likewise, a term “a,” “an,” or “the” does not indicate limitation in number, but specifies the presence of at least one. A term “comprises,” “comprising,” “includes,” “including”, or the like means that an element or article ahead of this term encompasses element(s) or article(s) listed behind this term and its(their) equivalents, but does not preclude the presence of other elements or articles. The phrases “connect”, “connected”, etc., are not intended to define a physical connection or mechanical connection, but may include an electrical connection, directly or indirectly. “On,” “under,” “left,” “right” or the like is only used to describe a relative positional relationship, and when the absolute position of a described object is changed, the relative positional relationship might also be changed accordingly.

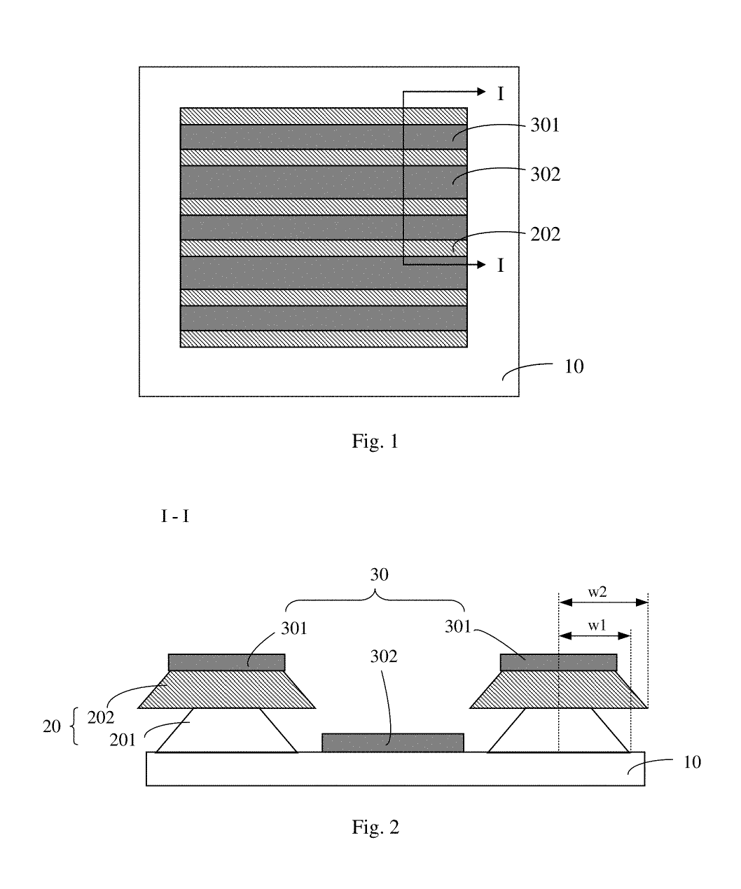

As illustrated by FIG. 1 and FIG. 2, an embodiment according to the present disclosure provides an electrode structure, comprising: a substrate 10, a plurality of strip-like partitions 20 disposed on the substrate 10, and an electrode 30 covering on a surface of the substrate 10. The electrode 30 comprises a first portion 301 located on a surface of each of the strip-like partitions 20 and a second portion 302 located between two adjacent strip-like partitions 20. Each of the strip-like partitions 20 comprises an upper layer 202 and a lower layer 201 which are stacked with each other, and the upper layer 202 and the lower layer 201 are made of different materials. The bottom surface of the upper layer 202 completely covers the top surface of the lower layer 201, and the width of the bottom surface of the upper layer 202 is larger than the width of the top surface of the lower layer 201 in a plane perpendicular to an extending direction of the strip-like partitions 20.

The plurality of strip-like partitions 20 are disposed in parallel and extend along a horizontal direction in FIG. 1, and FIG. 2 illustrates a sectional view perpendicular to the extending direction in FIG. 1. It can be seen from the drawings that the width of the bottom surface of the upper layer 202 is larger than the width of the top surface of the lower layer 201, so that the first portion 301 can be separated and insulated from the second portion 302. In one example, in order to further ensure that the first portion 301 and the second portion 302 of the electrode 30 are separated from each other, the upper surface of the lower layer 201 can be higher than the upper surface of the second portion 302, for example, higher than the upper surface of the second portion 302 by 600 nm. In FIG. 2, a section formed of a stacked structure of the upper layer 202 and the lower layer 201 are in axial symmetry. In some embodiments, the maximum width w2 on a side of the upper layer 202 is larger than the maximum width w1 on the same side of the lower layer 201 by from 1 μm-2 μm. However, in other embodiments of the present disclosure, the stacked structure may not be in axial symmetry, for example, the center of the lower layer 201 may be shifted by a certain distance with respect to the center of the upper layer 202, as long as the bottom surface of the upper layer can completely cover the top surface of the lower layer. In this case, the width of the bottom surface of the upper layer 202 may be larger than that of the bottom surface of the lower layer 201 by from 2 μm-4 μm. In an ideal situation, the section of each layer shall have a rectangle shape; however, due to the influence of an actual etching process, the actual section of each layer generally has a trapezoid shape.

In an example, one of the upper layer 202 and the lower layer 201 is made of a resin material, and the other one is made of an inorganic insulating material. For example, the layer made of an inorganic insulating material has a thickness of 0.2 μm-1 μm, and if the layer made of an inorganic insulating material is too thin, the strength is not enough; if the layer made of an inorganic insulating material is too thick, there will be production capacity and thin film stress problems; and the thickness may be 0.4 μm-0.6 μm. In an example, the layer made of a resin material has a thickness of 1 μm-3 μm, and if the layer made of a resin material is too thin, the isolation effect is bad; if the layer made of a resin material is too thick, there will be material waste and thin film stress problems, and the thickness may be 1.5 μm-2 μm.

In an example, the upper layer 202 may be made of an inorganic insulating material, such as: SiNx, SiOx, SiON, AlOx, and thus has high strength; even after being spin-coated and then being edged, the upper layer will not be damaged; the lower layer 201 may be made of a resin material, for example, a thermal curing resin or a light-curable resin, comprising conventional positive or negative photoresist, epoxy resin or the like, these materials have temperature tolerance above 130␣, have certain mechanical strength, and have a good isolation effect.

In another example, the upper layer 202 may be made of a resin material, and the lower layer 201 may be made of an inorganic insulating material. In this case, in order to conveniently manufacture the strip-like partitions, the resin material may be photosensitive resin, so that it can be used as a mask after being patterned. The specific examples of the inorganic insulating material may refer to the above examples.

In the present embodiment, the strip-like partition adopts a two-layer structure composed of an inorganic insulating layer and a resin layer, which not only improves the mechanical strength but also facilitates insulation between two portions (a first portion 301 and a second portion 302) of the electrode 30, so as to avoid short circuit and improve the stability of the electrode structure. The strip-like partition may be widely applied in the display technical field, especially in manufacturing electrode patterns, which are insulated from each other, on a substrate. Hereafter, the case where the strip-like partition is applied in an organic light emitting unit is described as an example, but the scope of the present disclosure is not limited thereto.

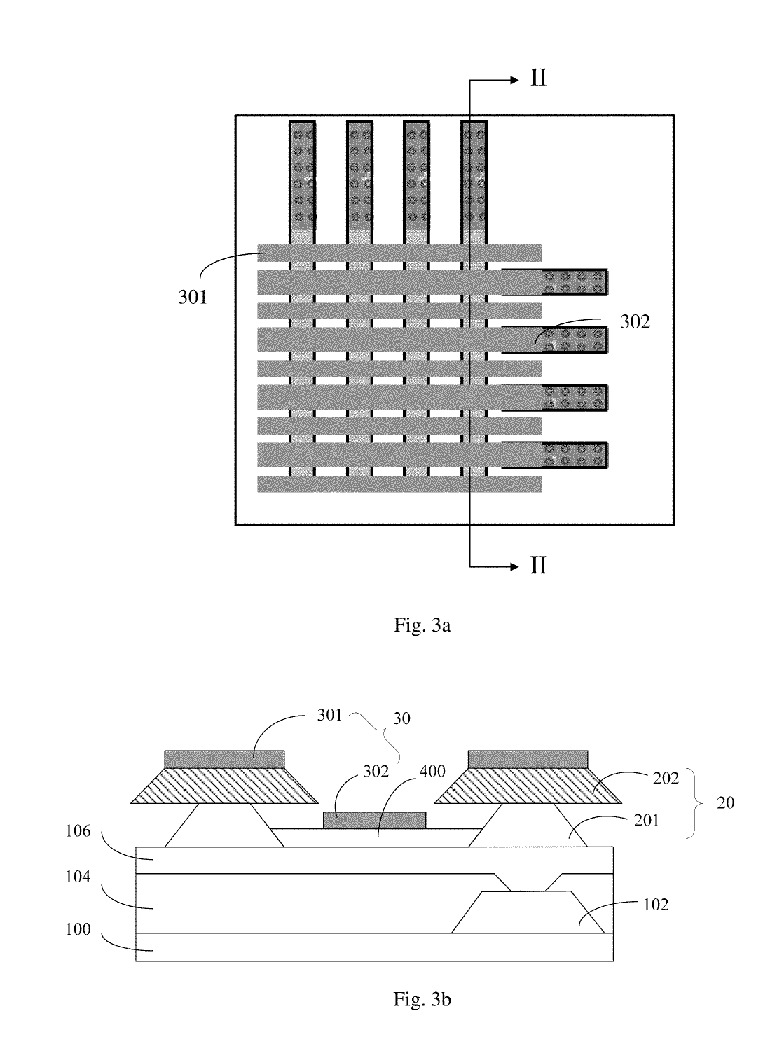

As illustrated by FIG. 3a and FIG. 3b, another embodiment of the present disclosure provides an organic light emitting unit, which comprises: a base substrate 100; a metal electrode 102, an interlayer dielectric layer 104, and a first electrode 106 which are sequentially disposed on the base substrate 100; a plurality of strip-like partitions 20 disposed on the first electrode 106; and an organic light emitting layer 400 disposed between two adjacent strip-like partitions 20. The organic light emitting unit further comprises a second electrode 30 covering a surface of the substrate, the second electrode 30 comprises a first portion 301 located on a surface of each of the strip-like partitions and a second portion 302 located on the organic light emitting layer 400. Each of the strip-like partitions 20 comprises a first material layer located in the lower layer 201 and a second material layer located in the upper layer 202. The first material layer and the second material layer are made of different materials. For example, one of the first material layer and the second material layer is made of a resin material, and the other layer is made of an inorganic insulating material. The bottom surface of the upper layer 202 completely covers the top surface of the lower layer 201, and a width of the bottom surface of the upper layer 202 is larger than that of the top surface of the lower layer 201, in this way the first portion 301 and the second portion 302 of the second electrode 30 are separated and insulated from each other.

In the present embodiment, the configuration, material and thickness of the strip-like partitions 20 are the same as the abovementioned embodiments, and the redundant portions are omitted here. Unlike the abovementioned embodiments, the present embodiment disposes a plurality of function layers on the base substrate 100, which comprise a metal electrode 102, an interlayer dielectric layer 104, a first electrode 106, and an organic light emitting layer 400. Herein, for example, the base substrate 100 may adopt a glass substrate, a quartz substrate, a plastic substrate or other transparent substrate. The metal electrode 102 may be made of a metal material or an alloy material. The interlayer dielectric layer 104 may be made of an insulating material, such as SiOx and SiNx. The interlayer dielectric layer 104 is provided with a via hole therein, and the first electrode 106 is electrically connected with the metal electrode 102 through the via hole.

In the present embodiment, the first electrode 106 serves as a cathode, the second electrode 30 serves as an anode, and the organic light emitting layer 400 is sandwiched between the cathode and the anode. It can be understood that the structure of the organic light emitting unit illustrated in FIG. 3b is only schematic, in the other embodiments of the present disclosure, the metal electrode 102 and the interlayer dielectric layer 104 may be omitted. Besides, a hole injection layer, a hole transport layer, an electron injection layer, an electron transport layer and the like can be additionally disposed between the cathode 105 and the anode 30, so as to further improve the performance of the organic light emitting unit.

In the present embodiment, the cathode partition of the organic light emitting unit adopts a two-layer structure composed of an inorganic insulating layer and a resin layer, which not only improves the mechanical strength, but also conveniently insulate the two portions (the first portion 301 and the second portion 302) of the second electrode from each other, so as to avoid short circuit and improve the stability of the cathode.

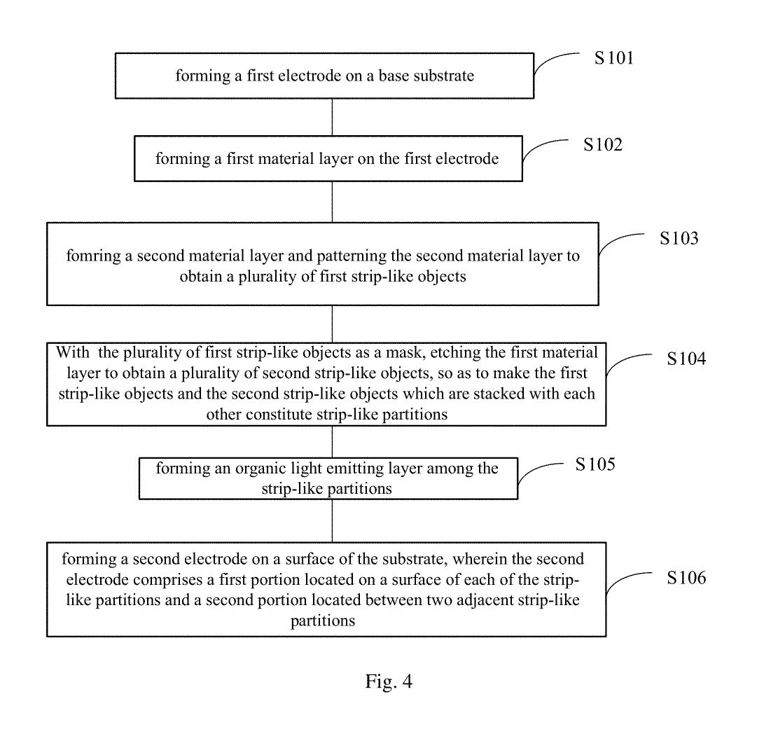

Yet another embodiment according to the present disclosure provides a manufacturing method of an organic light emitting unit, as illustrated by FIG. 4, the method comprises the following steps:

S101: forming a first electrode on a base substrate;

S102: forming a first material layer on the first electrode;

S103: forming a second material layer on the first material layer and then patterning the second material layer to obtain a plurality of first strip-like members;

S104: etching the first material layer with the plurality of first strip-like members as a mask to obtain a plurality of second strip-like members, whereby each of the first strip-like members and each of the second strip-like members which are stacked with each other constitute a strip-like partition;

S105: forming an organic light emitting layer among the plurality of strip-like partitions; and

S106: forming a second electrode on a surface of the substrate, wherein the second electrode comprises a first portion located on a surface of each of the strip-like partitions and a second portion located on a surface of the organic light emitting layer; the first material layer and the second material layer are made of different materials; a width of a bottom surface of the second material layer is larger than that of a top surface of the first material layer, and the bottom surface of the second material layer completely covers the top surface of the first material layer. In the present application, the expression “a width of the bottom surface of the second material layer is larger than a width of the top surface of the first material layer” or similar expressions refers to, as for each of the strip-like partitions, the width of the bottom surface of the second material layer is larger than the width of the top surface of the first material layer.

In an example, in order to manufacture the organic light emitting unit illustrated by FIG. 3b, the step S101 may further comprise: before forming the first electrode 106, forming a metal electrode 102 and a interlayer dielectric layer 104 on the base substrate 100, wherein the interlayer dielectric layer 104 is provided with a via hole therein, such that the first electrode 106 can be electrically connected with the metal electrode 102 through the via hole.

Hereafter, the manufacturing method of an organic light emitting unit will be further described by taking the case where the lower layer of strip-like partition 20 in the organic light emitting unit in FIG. 3b is a resin layer and the upper layer is an inorganic insulating layer as an example.

Another embodiment according to the present disclosure provides a manufacturing method, comprising the following steps:

S201: sequentially forming a metal electrode 102, an interlayer dielectric layer 104 and a first electrode 106 on a base substrate 100, wherein the interlayer dielectric layer 104 is provided with a via hole therein, the metal electrode 102 is electrically connected with the first electrode 106 through the via hole.

In an example, the step S201 may comprise the following steps S201a-S201e.

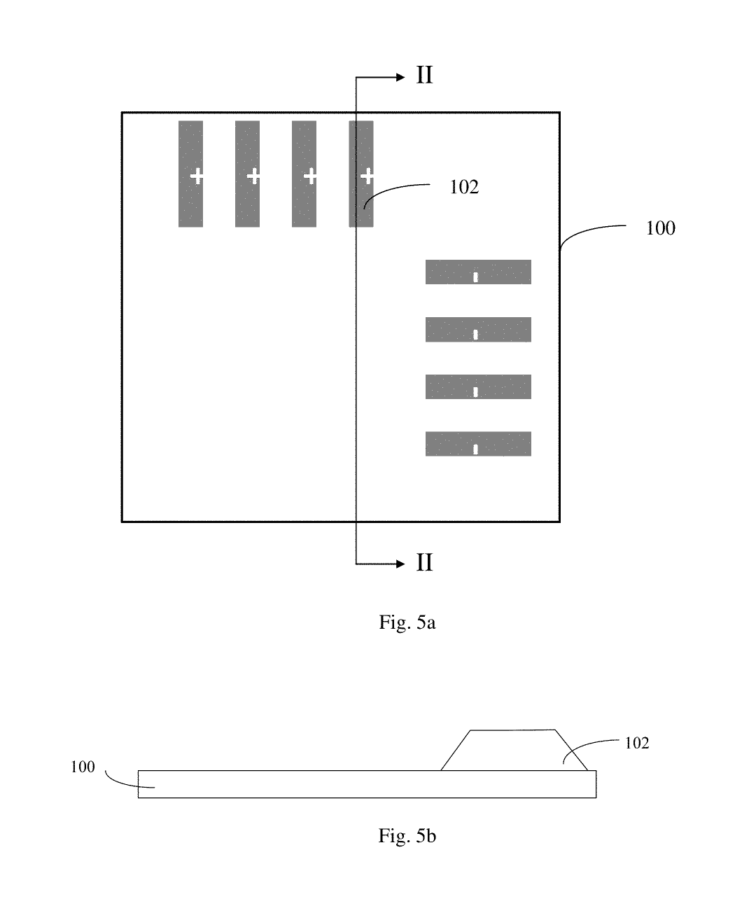

S201a: forming a metal thin film on a base substrate 100, and patterning the metal thin film to form a plurality of metal electrodes 102 through a patterning process, as illustrated by FIG. 5a and FIG. 5b.

FIG. 5a schematically illustrates a plan view of a substrate according to an embodiment of the present disclosure, and FIG. 5b is a sectional view along line II-II in FIG. 5a. For example, the metal thin film may be formed on the base substrate 100 by using a conventional depositing technology, for example, a sputtering process, a plasma enhanced chemical vapor deposition (PECVD) process, or an evaporation process. The metal thin film can adopt a metal or an alloy, comprising, but not limited to, molybdenum, aluminum, cuprum, titanium, neodymium or other metal or any alloy thereof. For example, the base substrate 100 may adopt a glass substrate, a quartz substrate, a plastic substrate or other transparent substrates. The metal electrode 102 has a long strip shape, comprising a plurality of positive electrodes extending along a vertical direction and a plurality of negative electrodes extending along a horizontal direction. The positive electrode is configured to import a gate electrode signal (positive voltage), for example, applied with a positive level, injecting holes into the organic light emitting layer through a hole injection layer and a hole transport layer; the negative electrode is configured to import a data signal (negative voltage), applied with a negative level, injecting electrons into the organic light emitting layer through an electron injection layer and an electron transport layer; and thus the light emitting layer can be driven to emit light. The “patterning process” in the text typically comprises the steps such as coating photoresist, exposing, developing, etching, and stripping. In order to form a specific pattern, a half tone mask plate or a gray tone mask plate may be used during the patterning process.

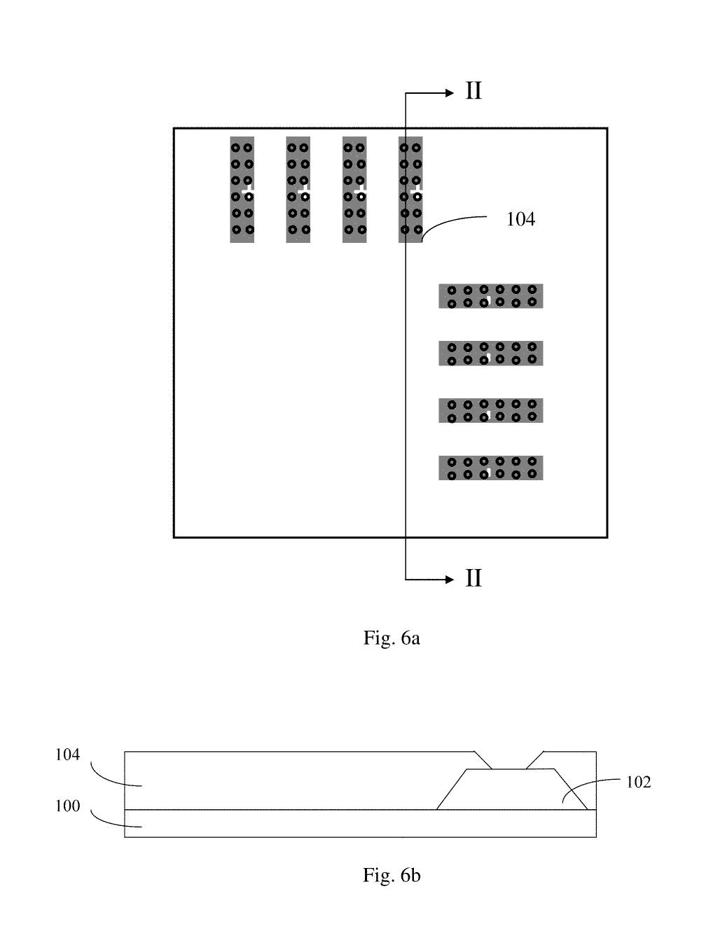

S201b: forming an inorganic material thin film on the plurality of metal electrodes 102, and patterning the inorganic insulating thin film through a patterning process to form an interlayer dielectric layer 104 covering each of the metal electrodes, wherein the interlayer dielectric layer 104 is provided with a plurality of via holes, as illustrated by FIGS. 6a and 6b, and FIG. 6b only illustrates one via hole as an example.

For example, the interlayer dielectric layer 104 is made of an inorganic insulating material, for example, SiOx, SiNx or SiON.

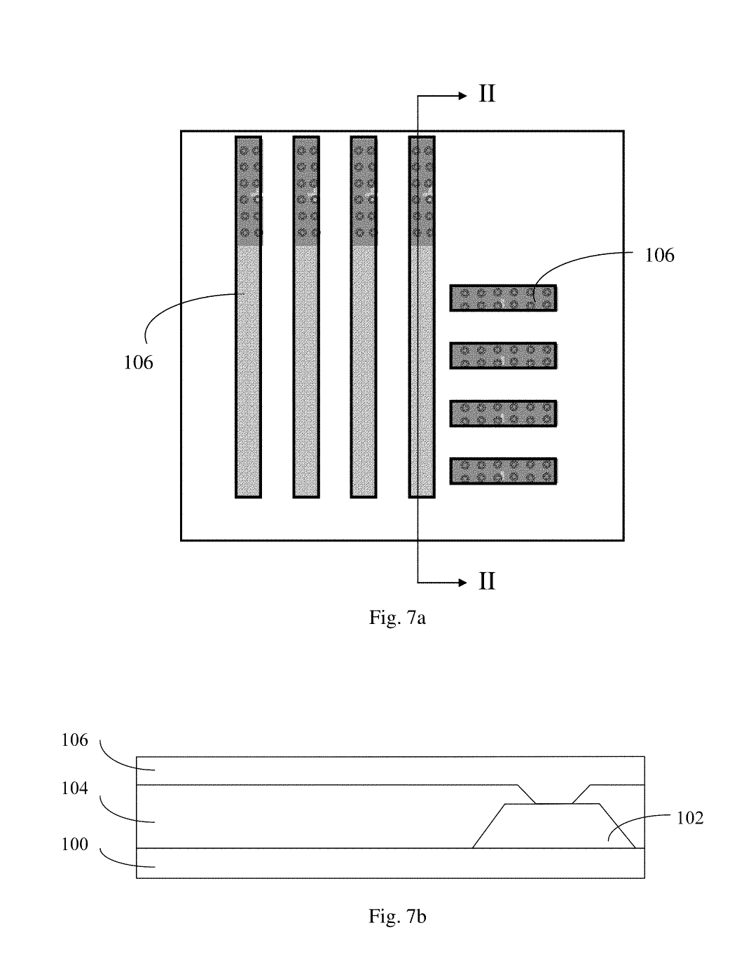

S201c: forming a transparent conductive thin film on the interlayer dielectric layer 104, and patterning the transparent conductive thin film through a patterning process to form a plurality of first electrodes 106, as illustrated by FIGS. 7a and 7b.

For example, the transparent conductive thin film may adopt ITO (Indium tin oxide), IZO (Indium zinc oxide) or other transparent conductive material. The first electrodes 106 cover both the positive electrodes and the negative electrodes, wherein the first electrodes 106 on the positive electrodes are extended as strip electrodes, perpendicular to an extending direction of the plurality of negative electrodes, and are configured to import a positive electrode signal; the first electrodes 106 on the negative electrodes only cover rightly on the electrode, and are configured to connect the evaporated negative metal, and import a negative electrode signal

The abovementioned manufacturing method of an organic light emitting unit further comprises the following steps.

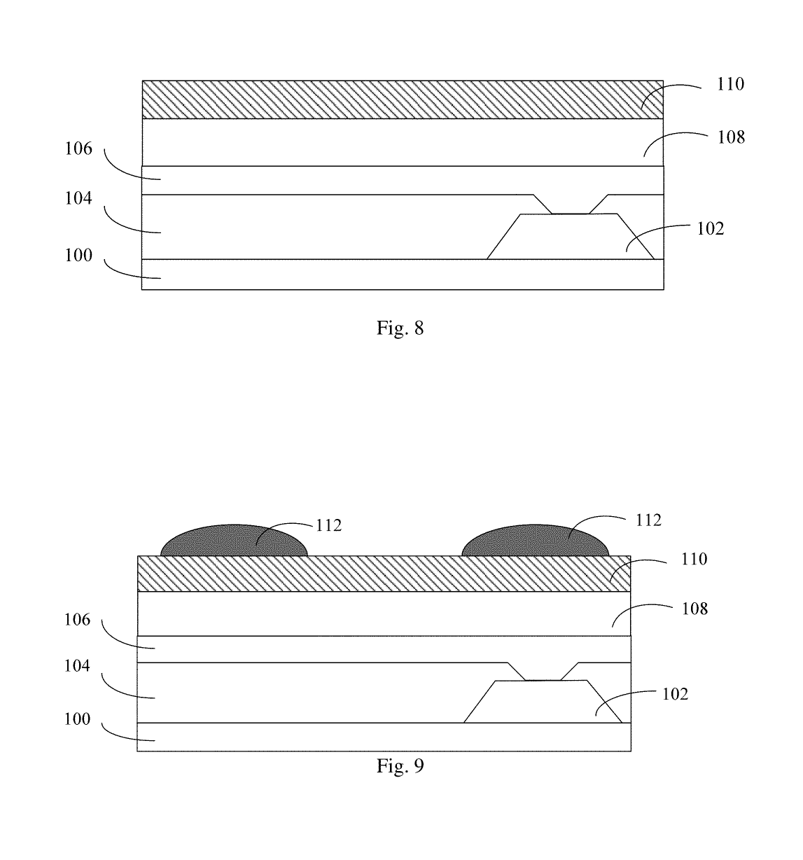

S202: forming a resin thin film 108 used for forming the first material layer on the first electrode 106, then forming an inorganic insulating thin film 110 used for forming the second material layer on the resin thin film 108, as illustrated by FIG. 8.

For example, a drop coating method is used to coat resin liquid on the first electrode. The resin liquid may be thermal curing resin or light-curable resin, and then thermally curing or curing with light the resin liquid to form a resin thin film 108. Because the abovementioned resin is conventional positive or negative photoresist, epoxy resin or the like, these materials have temperature tolerance above 130□, have certain mechanical strength, and have good isolation effect and low costs. Afterwards, an inorganic insulating thin film 110 is disposed on the resin thin film 108 through a PECVD method. The inorganic insulating thin film may employ an inorganic insulating material, for example, SiNx, SiOx, SiON or AlOx, and thus has high strength; even after being spin-coated and then edged, the inorganic insulating thin film will not be damaged.

For example, the inorganic insulating thin film 110 has a thickness of 0.2 μm-1 μm, and if this thin film made of an inorganic insulating material is too thin, the strength is not enough, and if this thin film is too thick, there will be production capacity and thin film stress problems. In some embodiments; the thickness thereof may be 0.4 μm-0.6 μm. In an example, a resin material thin film has a thickness of 1 μm-3 μm, if this thin film of the resin material is too thin, the isolation effect is bad, and if this thin film of the resin material is too thick, there will be material waste and thin film stress problems, and the thickness thereof may be 1.5 μm-2 μm.

S203: forming photoresist 112 on an inorganic insulating thin film 110, and patterning the photoresist 112 through exposing and developing processes to expose a part of the inorganic insulating thin film, as illustrated by FIG. 9.

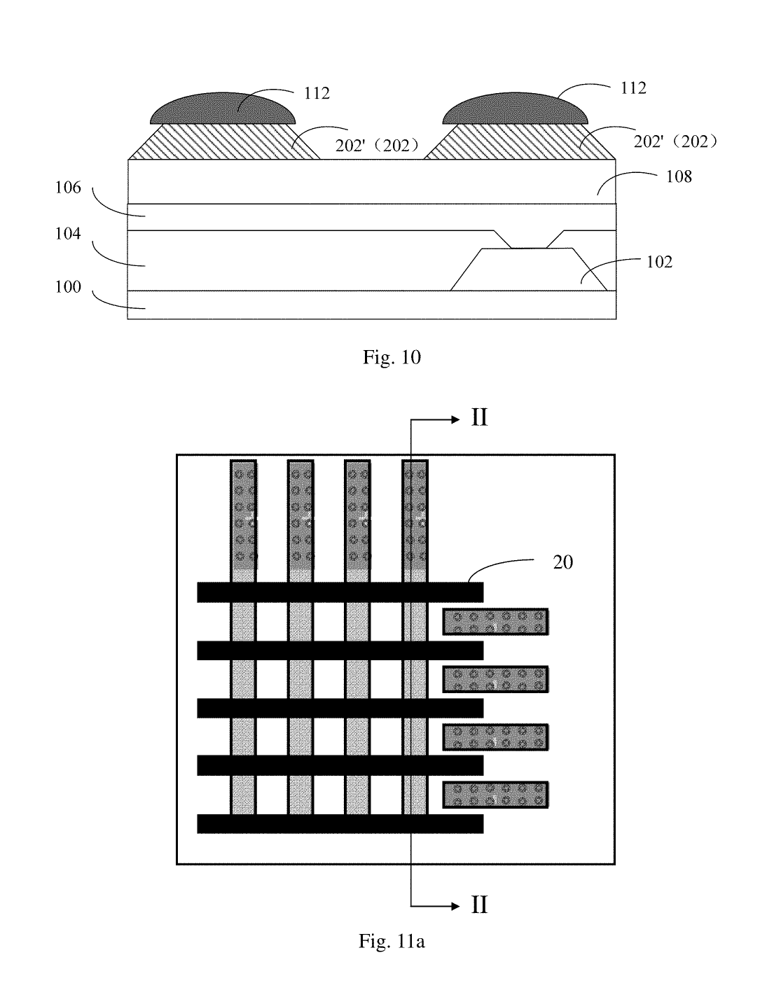

S204: etching the exposed part of the inorganic insulating thin film through a dry etching method to form a plurality of first strip-like members 202′ made of an inorganic insulating material (i.e., an upper layer 202 in FIG. 3), as illustrated by FIG. 10.

For example, in the dry etching process, the etching gas adopts a mixed gas of fluoride-containing gas and oxygen. For example, the fluoride-containing gas may be SF6 or CF4, the gas flow may be 50 sccm-800 sccm, for example, the gas flow may be 350-400 sccm; if the gas flow is too low, the etching rate is relatively slow and not convenient for mass production; if the gas flow is too high, the evenness is relatively bad. For example, the gas flow of oxygen may be 0-300 sccm, or 100 sccm-150 sccm, whose function is mainly used to increase the etching rate to some degree. In one example, the etching gas may comprise helium (He), for example, its gas flow may be 0-200 sccm, which can increase the etching evenness to some degree. For example, the etching power is 200W-800W, and the etching rate is generally 50 Å-300 Å, for example, 150 Å-200 Å, so as to improve the efficiency, and too high speed will cause bad evenness. The etching time is 20 seconds to 400 seconds, and too long etching time will cause overheat of the substrate and generate deformation.

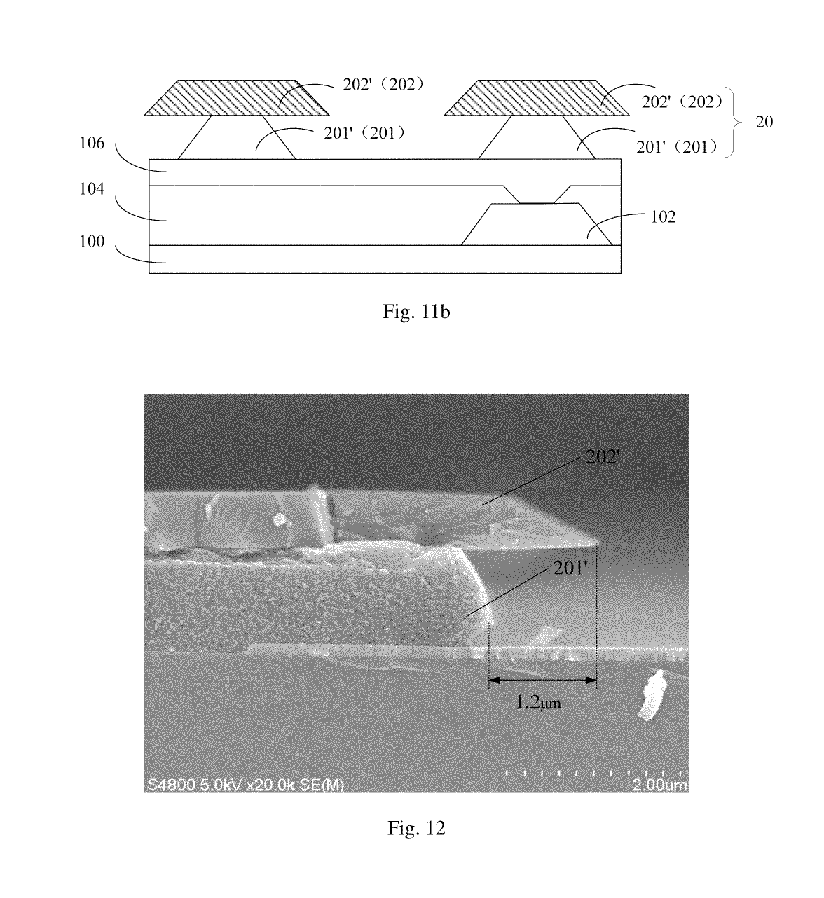

S205: with the plurality of first strip-like members 202′ as a mask, treating the resin thin film 108 through an ashing process to simultaneously remove a part of the resin thin film and the residual photoresist, so as to obtain a plurality of second strip-like members 201′ (a lower layer 201 in FIG. 3) made of the resin material, as illustrated by FIGS. 11a and 11b. The first strip-like member 202′ and the second strip-like member 201′ constitute the strip-like partitions 20.

For example, in the ashing process, oxygen plasma can be utilized to ash the resin thin film, so as to avoid damaging the first strip-like members 202′, and can simultaneously remove the residual photoresist remained on the first strip-like members 202′. The ashing time can be determined according to the thickness of the resin thin film to be removed and the expected width of the second strip-like members 201′. In the present embodiment, the ashing time is about 100 seconds to 200 seconds, for example, 150 seconds. At the interface where the first strip-like member 202′ contacts the second strip-like member 201′, the width of the first strip-like member 202′ is larger than the width of the second strip-like member 201′, such that it can be guaranteed that the metal electrode is broken at the strip-like partitions 20 when the metal electrode is evaporated in the subsequent step. In some embodiments, a maximum width of a side of the first strip-like member 202′ is larger than that of the second strip-like member 201′ at the same side, for example by 1 μm-2 μm. FIG. 12 is the scanning electron microscope (SEM) picture of the substrate after the step S205 is completed. From the picture, it can be seen that the maximum width of a side of the first strip-like member 202′ is larger than that of the second strip-like member 201′ at the same side, for example, by 1.2 μm from measure. In some embodiments, the maximum widths of the first strip-like member 202′ at the two sides thereof are respectively larger than those of the second strip-like member 201′ at the same two sides by 1 μm-2 μm.

S206: forming an organic light emitting layer 400 among the plurality of strip-like partitions 20.

For example, the organic light emitting layer 400 is deposited in the interspaces among the strip-like partitions through an evaporation method, the organic light emitting layer adopts small molecules for OLED or a quantum dot material, because these materials have isotropy, the organic light emitting layer is separately physically contacted with the second strip-like members 201′ located at two sides of the organic light emitting layer.

S207: forming a second electrode 30 on a surface of the substrate, the second electrode 30 comprises a first portion 301 located on the surface of each of the strip-like partitions 20 and a second portion 302 located on the surface of the organic light emitting layer, as illustrated by FIGS. 3a and 3b.

For example, a second electrode is formed on the surface of the substrate through an evaporation method, and the metal may be one or more selected from a group consisting of magnesium, argentums and aluminum. Because the width of the first strip-like members 202′ is larger than that of the second strip-like members 201′, the first portion 301 and the second portion 302 of the second electrode 30 are broken due to the uncontinuous interface between the first strip-like member 202′ and the second strip-like member 201′, and are separated and insulated from each other. In the present embodiment, the first electrode 106 serves as a cathode, the second electrode 30 serves as an anode, and the organic light emitting layer 400 is sandwiched between the cathode and the anode.

In the present embodiment, the cathode of the organic light emitting unit is in a two-layer structure composed of a resin layer/an inorganic insulating layer, which not only improves the mechanical strength, but also facilitates to insulate the two electrode portions (the first portion 301 and the second portion 302) from each other, so as to avoid short circuit, and improve the stability of the cathode.

Another embodiment according to the present disclosure provides a manufacturing method of an organic light emitting unit, unlike the abovementioned embodiments, in the present embodiment, the lower layer of the strip-like partitions 20 is an inorganic insulating layer, and the upper layer is a resin layer. The method comprises the following steps:

S301: same as step S201.

In one example, step S301 may comprise S201a-S201c, as illustrated by FIGS. 5a-7b.

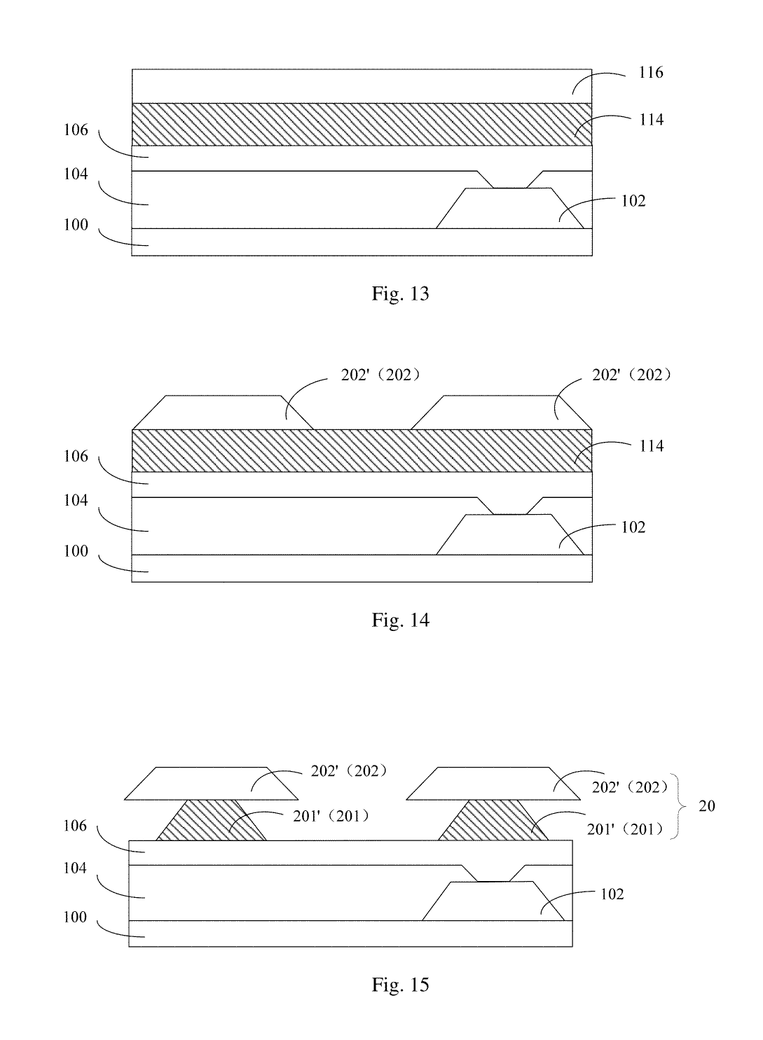

S302: forming an inorganic insulating thin film 114 used for forming the first material layer on the first electrode 106, then forming a resin thin film 116 used for forming the second material layer on the inorganic insulating thin film, as illustrated by FIG. 13; then, patterning the resin thin film 116 through exposing and developing processes to obtain a plurality of first strip-like members 202′ made of a resin material and expose a part of the inorganic insulating thin film, as illustrated by FIG. 14.

S303: with the plurality of first strip-like members 202′ as a mask, etching the exposed inorganic insulating thin film 114 through a dry etching process to obtain a plurality of second strip-like members 201′ made of the inorganic insulating material, as illustrated by FIG. 15. The first strip-like members 202′ and the second strip-like members 201′ constitute the strip-like partitions 20.

In the dry etching process, the etching gas(es) is the same as the abovementioned embodiments.

S304: same as step S206.

S305: same as step S207.

In the present embodiment, the inorganic insulating thin film 114 has the same material and thickness as the inorganic insulating thin film 110 in the abovementioned embodiments. However, the resin thin film in the present embodiment adopts photosensitive resin, such as DPI-1000, which is more favorable for serving as a mask and reduces the costs. The forming process of the thin film is same as the abovementioned embodiments. Because the width of the first strip-like members 202′ is larger than that of the second strip-like members 201′, the first portion 301 and the second portion 302 of the second electrode 30 are separated and insulated with each other.

In the present embodiment, the cathode of the organic light emitting unit adopts a two-layer structure made of an inorganic insulating layer/a resin layer, which not only improves the mechanical strength, but also facilitates to insulate two electrode portions (the first portion 301 and the second portion 302) form each other, so as to avoid short circuit and improve the stability of the cathode.

The organic light emitting layer in the organic light emitting unit provided by the embodiments of the present disclosure may be any kind of electroluminescence layer, thus, the embodiments of the present disclosure also relate to an electroluminescence unit. Besides, the embodiments of the present disclosure further provide a display apparatus comprising the organic light emitting unit or electroluminescence unit.

The foregoing are merely specific embodiments of the disclosure, but not limitative to the protection scope of the present disclosure. Therefore, the protection scope of the disclosure should be defined by the accompanying claims.

The present disclosure claims the benefits of Chinese patent application No. 201510482988.4, which was filed on Aug. 3, 2015 and is fully incorporated herein by reference as part of this application.

1. An electrode structure, comprising:
a substrate;
a plurality of strip-like partitions disposed on the substrate; and
an electrode covering a surface of the substrate, wherein the electrode comprises a first portion located on a surface of each of the strip-like partitions and a second portion located between two adjacent strip-like partitions,
wherein each of the strip-like partitions comprises an upper layer and a lower layer which are stacked with each other, the upper layer and the lower layer are made of different materials; a bottom surface of the upper layer completely covers a top surface of the lower layer, and a width of the bottom surface of the upper layer is larger than a width of the top surface of the lower layer in a plane perpendicular to an extending direction of the strip-like partitions.

2. The electrode structure according to claim 1, wherein an upper surface of the lower layer is higher than an upper surface of the second portion of the electrode.

3. The electrode structure according to claim 1, wherein the width of the bottom surface of the upper layer is larger than a width of a bottom surface of the lower layer by 2 μm-4 μm.

4. The electrode structure according to claim 1, wherein a section of a stacked layer constitued by the upper layer and the lower layer is in axial symmetry in the plane perpendicular to an extending direction of the strip-like partitions.

5. The electrode structure according to claim 1, wherein one of the upper layer and the lower layer is made of a resin material, and other one is made of an inorganic insulating material.

6. The electrode structure according to claim 5, wherein a thickness of the layer made of the inorganic insulating layer is 0.2 μm-1 μm, and a thickness of the layer made of the resin material is 1 μm-3 μm.

7. An organic light emitting unit, comprising:
a base substrate;
a first electrode disposed on the base substrate;
a plurality of strip-like partitions disposed on the first electrode;
an organic light emitting layer disposed between two adjacent strip-like partitions; and
a second electrode covering a surface of the base substrate, wherein the second electrode comprises a first portion located on a surface of each of the strip-like partitions and a second portion located between two adjacent strip-like partitions,
wherein each of the strip-like partitions comprises a first material layer located at an lower layer and a second material layer located at an upper layer, the first material layer and the second material layer are made of different materials; a bottom surface of the upper layer completely covers a top surface of the lower layer, and a width of the bottom surface of the upper layer is larger than a width of the top surface of the lower layer in a plane perpendicular to an extending direction of the strip-like partitions.

8. The organic light emitting unit according to claim 7, wherein the width of the bottom surface of the upper layer is larger than a width of a bottom surface of the lower layer by 2 μm-4 μm.

9. The organic light emitting unit according to claim 7, wherein one of the first material layer and the second material layer is made of a resin material, and the other one is made of an inorganic insulating material.

10. The organic light emitting unit according to claim 9, wherein a thickness of the layer made of the inorganic insulating material is 0.2 μm-1 μm, and a thickness of the layer made of the resin material is 1 μm-3 μm.

11. A manufacturing method of an organic light emitting unit, comprising:
forming a first electrode on a base substrate;
forming a first material layer on the first electrode;
forming a second material layer and patterning the second material layer to obtain a plurality of first strip-like members;
etching the first material layer by way of the plurality of first strip-like members as a mask to obtain a plurality of second strip-like members, so as to allow the first strip-like members and the second strip-like members which are stacked with each other constitute strip-like partitions;
forming an organic light emitting layer among the strip-like partitions; and
forming a second electrode on a surface of the base substrate, wherein the second electrode comprises a first portion located on a surface of each of the strip-like partitions and a second portion located between two adjacent strip-like partitions,
wherein the first material layer and the second material layer are made of different materials; in a plane perpendicular to an extending direction of the strip-like partitions, a width of a bottom surface of the second material layer is larger than a width of a top surface of the first material layer, and the bottom surface of the second material layer completely covers the top surface of the lower layer.

12. The method according to claim 11, wherein the first material layer is made of a resin material, and the second material layer is made of an inorganic insulating material.

13. The method according to claim 12, further comprising:
forming a resin thin film used for the first material layer, and then forming an inorganic insulating thin film used for the second material layer on the resin thin film;
forming photoresist on the inorganic insulating thin film, and patterning the photoresist through exposing and developing processes to expose a part of the inorganic insulating thin film; and
etching the exposed part of the inorganic insulating thin film through a dry etching process to obtain the plurality of first strip-like members made of the inorganic insulating material.

14. The method according to claim 13, further comprising:
with the plurality of first strip-like members as a mask, treating the resin thin film through an ashing process to simultaneously remove a part of the resin thin film and residual photoresist, so as to obtain the plurality of second strip-like members made of the resin material.

15. The method according to claim 14, wherein in the ashing process, an ashing gas is an oxygen plasma.

16. The method according to claim 11, wherein the first material layer is made of an inorganic insulating material, and the second material layer is made of a resin material.

17. The method according to claim 16, further comprising:
forming an inorganic insulating thin film used for the first material layer, and then forming a resin thin film used for the second material layer on the inorganic insulating thin film; and
patterning the rein thin film through exposure and development processes to obtain the plurality of first strip-like members made of the resin material and expose a part of the inorganic insulating thin film.

18. The method according to claim 17, further comprising:
with the plurality of first strip-like members as a mask, ething the exposed inorganic insulating thin film to obtain the plurality of second strip-like members made of the inorganic insulating material.

19. The method according to claim 16, wherein the resin material is photosensitive resin.
